(19) United States
(12) Patent Application Publication
(10) Pub. No.: US 2021/0067725 A1
(43) Pub. Date: Mar. 4, 2021

(54) LINEAR IMAGE SENSOR

(71) Applicant: HAMAMATSU PHOTONICS K.K., Hamamatsu-shi, Shizuoka (JP)

(72) Inventor: Tetsuya TAKA, Hamamatsu-shi, Shizuoka (JP)

(73) Assignee: HAMAMATSU PHOTONICS K.K., Hamamatsu-shi, Shizuoka (JP)

(21) Appl. No.: 16/321,570

(22) PCT Filed: Aug. 22, 2017
(86) PCT No.: PCT/JP2017/029962

§ 371 Date: Jan. 29, 2019

(30) Foreign Application Priority Data
Aug. 29, 2016 (JP) 2016-166673

(51) Int. Cl. H04N 5/3745; H01L 27/146

(52) U.S. Cl. CPC H04N 5/37457; H01L 27/14636; H01L 27/14643; H01L 27/14612

(57) ABSTRACT

A linear image sensor includes N units, a readout circuit, and a control unit. Each unit includes a photodiode and a source follower amplifier. The source follower amplifier includes a MOS transistor, an operation control switch, and a current source. A gate of the MOS transistor is connected to a cathode of the photodiode via the MOS transistor. The operation control switch is provided between a source of the MOS transistor and a connection node. The current source is provided between the connection node and a second reference potential input terminal.

### TECHNICAL FIELD

The present invention relates to a linear image sensor.

### BACKGROUND ART

A linear image sensor having a configuration in which a plurality of units each including a photodiode and an amplifier are arranged one-dimensionally is known (see Patent Documents 1 and 2). In each unit of the linear image sensor, the photodiode generates a charge according to light incidence, and the amplifier outputs a voltage value according to an amount of charge generated in the photodiode.

### CITATION LIST

### Patent Literature

Patent Document 1: Japanese Patent Application Laid-Open Publication No. 2001-141562

Patent Document 2: Japanese Patent Application Laid-Open Publication No. 2002-534005

### SUMMARY OF INVENTION

### Technical Problem

The linear image sensor having the configuration as described above has a problem that it is difficult to suppress power consumption.

An object of the present invention is to provide a linear image sensor capable of suppressing power consumption.

### Solution to Problem

A linear image sensor according to the present invention is a linear image sensor including a plurality of units each outputting a voltage value according to an incident light amount arranged one-dimensionally. In the linear image sensor, each of the plurality of units includes (1) a photodiode for generating a charge according to light incidence; and (2) a source follower amplifier including a MOS transistor having a gate connected to one terminal of the photodiode and a drain connected to a first reference potential input terminal, an operation control switch provided between a source of the MOS transistor and a connection node, and a current source provided between the connection node and a second reference potential input terminal, the source follower amplifier for outputting a voltage value according to a voltage value of the gate of the MOS transistor from the connection node in a period in which the operation control switch is in an ON state.

### Advantageous Effects of Invention

The linear image sensor according to the present invention can suppress power consumption.

### BRIEF DESCRIPTION OF DRAWINGS

FIG. 1 is a diagram illustrating a configuration of a linear image sensor 1 of an embodiment.

FIG. 2 is a diagram illustrating a first configuration example of each unit 10ₙ.

FIG. 3 is a timing chart illustrating an operation of the first configuration example of each unit 10ₙ.

FIG. 4 is a diagram illustrating a second configuration example of each unit 10ₙ.

FIG. 5 is a timing chart illustrating an operation of the second configuration example of each unit 10ₙ.

### DESCRIPTION OF EMBODIMENTS

Hereinafter, embodiments for carrying out the present invention will be described in detail with reference to the accompanying drawings. In the description of the drawings, the same elements will be denoted by the same reference signs, without redundant description. The present invention is not limited to these examples.

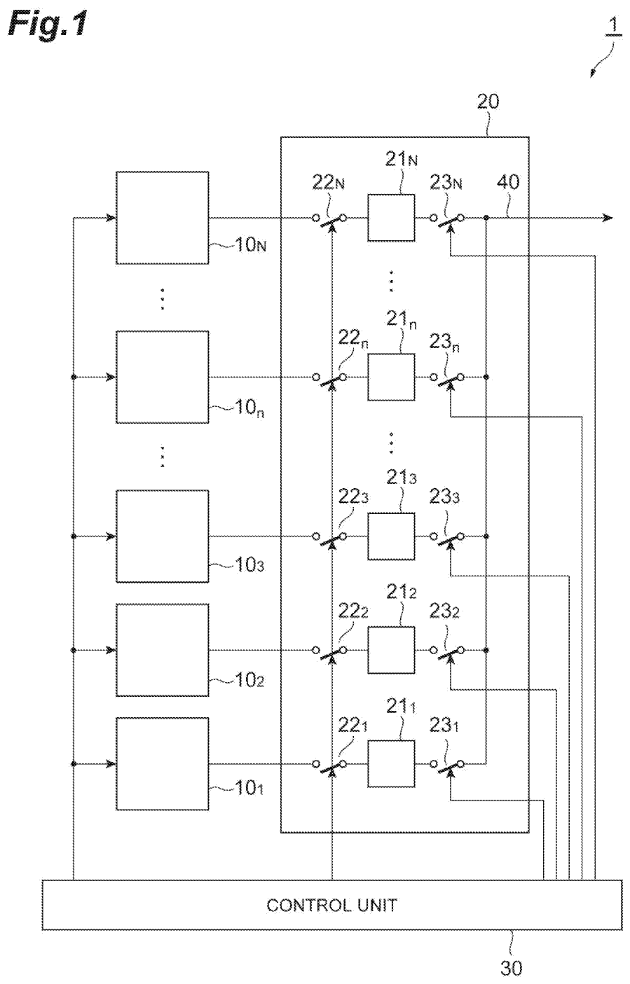

FIG. 1 is a diagram illustrating a configuration of a linear image sensor 1 according to an embodiment. The linear image sensor 1 includes N units 10₁ to 10_{N}, a readout circuit 20, and a control unit 30. The linear image sensor 1 is controlled by the control unit 30, and sequentially outputs a voltage value according to an incident light amount on a photodiode included in each unit 10ₙ from the readout circuit 20 to a video line 40. Here, N is an integer of 2 or more, and n is an integer of 1 or more and N or less.

The N units 10₁ to 10_{N} have a common configuration, and are arranged one-dimensionally at a fixed pitch. Each unit 10ₙ includes a photodiode, and outputs the voltage value according to the light amount incident on the photodiode.

The readout circuit 20 includes N hold circuits 21₁ to 21_{N}, N switches 22₁ to 22_{N}, and N switches 23₁ to 23_{N}. Each hold circuit 21ₙ is connected to an output terminal of the unit 10ₙ via the switch 22ₙ, and holds the voltage value output from the unit 10ₙ immediately before the switch 22ₙ changes from an ON state to an OFF state. Each hold circuit 21ₙ is connected to the video line 40 via the switch 23ₙ, and outputs the held voltage value to the video line 40 when the switch 23ₙ is in an ON state.

The switches 22₁ to 22_{N} are controlled by a control signal given from the control unit 30 such that the switches are switched between ON and OFF at the same timing. The switches 23₁ to 23_{N} are controlled by the control signal given from the control unit 30 to sequentially enter an ON state for a certain period. The control unit 30 not only controls turning ON and OFF of each of the switches 22₁ to 22_{N} and the switches 23₁ to 23_{N} of the readout circuit 20, but also controls an operation of each of the units 10₁ to 10_{N}.

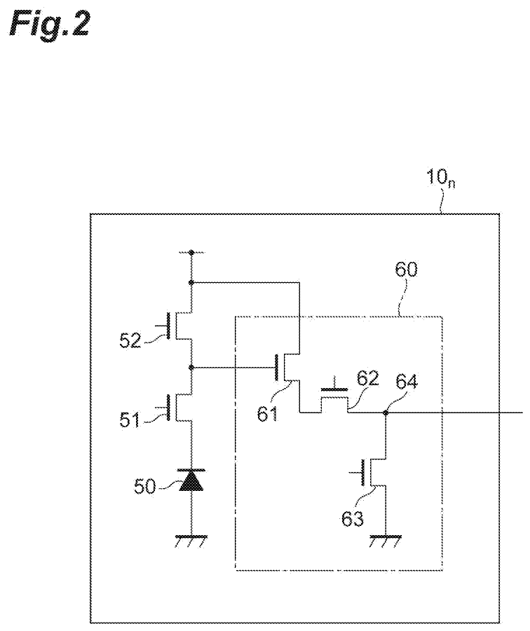

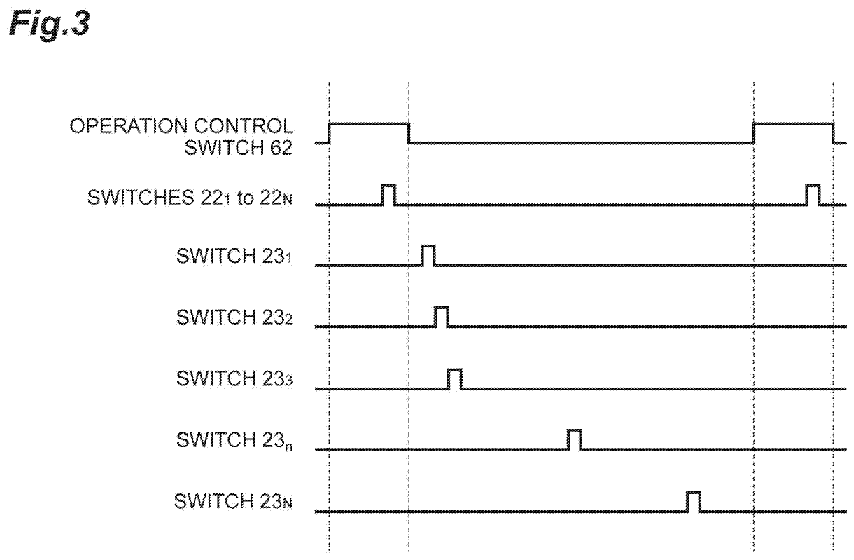

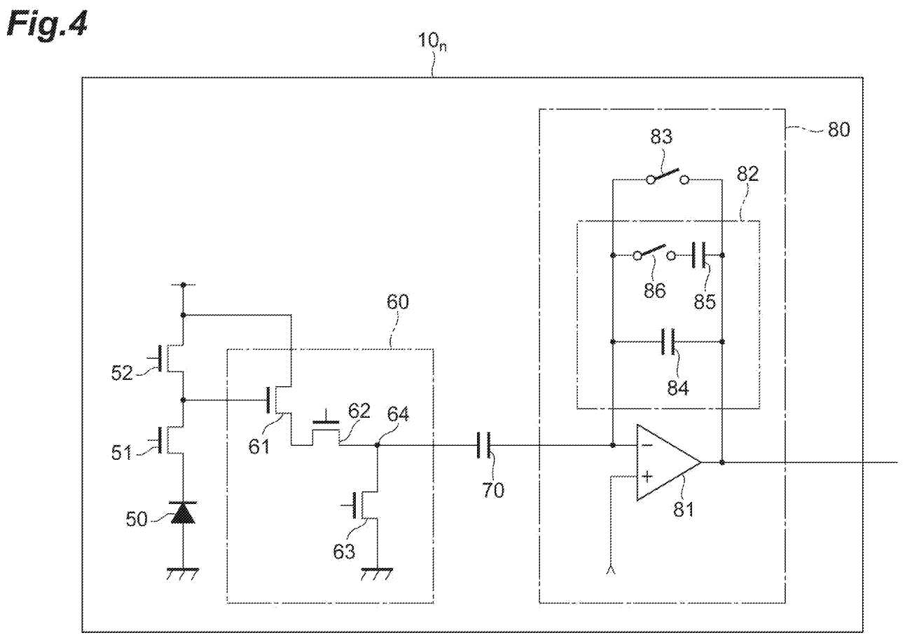

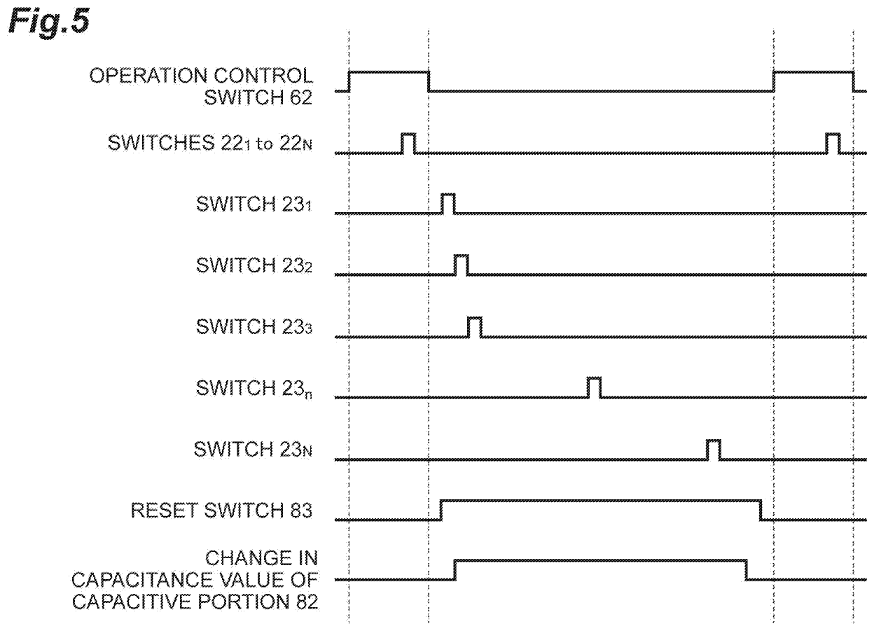

Hereinafter, a first configuration example of each unit 10ₙ will be described with reference to FIG. 2 and FIG. 3, and further, a second configuration example of each unit 10ₙ will be described with reference to FIG. 4 and FIG. 5.

FIG. 2 is a diagram illustrating a first configuration example of each unit 10ₙ. Each unit 10ₙ includes a photodiode 50, a MOS transistor 51, a MOS transistor 52, and a source follower amplifier 60. The source follower amplifier 60 includes a MOS transistor 61, an operation control switch 62, and a current source 63.

The photodiode 50 generates a charge according to light incidence. An anode of the photodiode 50 is connected to a second reference potential input terminal to which a second reference potential (for example, a ground potential) is input. A gate of the MOS transistor 61 is connected to a cathode of the photodiode 50 via the MOS transistor 51, and is connected to a first reference potential input terminal to which a first reference potential (for example, a power source potential) is input, via the MOS transistor 52. A drain of the MOS transistor 61 is connected to the first reference potential input terminal.

The operation control switch 62 is provided between a source of the MOS transistor 61 and a connection node 64. The operation control switch 62 may be configured by a MOS transistor. The current source 63 is provided between the connection node 64 and the second reference potential input terminal. The current source 63 may be configured by a MOS transistor or may be configured by a resistor.

Turning ON and OFF of each of the MOS transistors 51 and 52 is controlled by the control signal given from the control unit 30. When the MOS transistor 52 is in an ON state, a gate potential of the MOS transistor 61 is initialized. When the MOS transistors 51 and 52 are in an ON state, accumulation of charge in a junction capacitance of the photodiode 50 is initialized. When the MOS transistor 51 is in an ON state and the MOS transistor 52 is in an OFF state, the gate potential of the MOS transistor 61 depends on the incident light amount on the photodiode 50.

Further, turning ON and OFF of the operation control switch 62 is also controlled by the control signal given from the control unit 30. In a period in which the operation control switch 62 is in an ON state, a current flows from the first reference potential input terminal to the second reference potential input terminal via the MOS transistor 61, the operation control switch 62, and the current source 63, and a voltage value according to the gate potential of the MOS transistor 61 is output from the connection node 64. On the other hand, in a period in which the operation control switch 62 is in an OFF state, no current flows in the source follower amplifier 60 and the source follower amplifier enters a power-down state.

FIG. 3 is a timing chart illustrating an operation of the first configuration example of each unit 10ₙ. The operation control switch 62 is switched between ON and OFF with a fixed cycle. In the period in which the operation control switch 62 is in an ON state, the voltage value according to the gate potential of the MOS transistor 61 is output from the unit 10ₙ, and the voltage value output from the unit 10ₙ immediately before the switch 22ₙ changes from an ON state to an OFF state is held by the hold circuit 21ₙ. In the period in which the operation control switch 62 is in an OFF state, the N switches 23₁ to 23_{N} sequentially enter an ON state for a certain period, and the voltage values held by the N hold circuits 21₁ to 21_{N} are sequentially output to the video line 40.

In the period in which the operation control switch 62 is in an ON state, a current flows in the source follower amplifier 60, whereas in the period in which the operation control switch 62 is in an OFF state, no current flows in the source follower amplifier 60. A length of the period in which the operation control switch 62 is in an ON state can be, for example, about 15% of an ON and OFF switching cycle. In the linear image sensor 1 of the present embodiment, since the operation control switch 62 can be set to an OFF state when not in use, it is possible to suppress power consumption.

In addition, restarting of the source follower amplifier 60 when the operation control switch 62 changes from an OFF state to an ON state is fast. Therefore, when the source follower amplifier 60 is not in use, the operation control switch 62 enters an OFF state such that the source follower amplifier 60 can enter a power-down state.

FIG. 4 is a diagram illustrating a second configuration example of each unit 10ₙ. Each unit 10ₙ illustrated in FIG. 4 further includes a capacitive element 70 and a charge amplifier 80 in addition to the configuration illustrated in FIG. 2. The charge amplifier 80 includes an amplifier 81, a capacitive portion 82, and a reset switch 83.

The amplifier 81 includes an inverting input terminal, a non-inverting input terminal, and an output terminal. A fixed bias potential is input to the non-inverting input terminal of the amplifier 81. The inverting input terminal of the amplifier 81 is connected to the connection node 64 of the source follower amplifier 60 via the capacitive element 70.

The capacitive portion 82 is provided between the inverting input terminal and the output terminal of the amplifier 81. The capacitive portion 82 accumulates a charge of an amount according to a voltage value output from the source follower amplifier 60. A capacitance value of the capacitive portion 82 may be fixed, but is preferably variable. The capacitive portion 82 includes a capacitive element 84, a capacitive element 85, and a switch 86, and can change the capacitance value. The capacitive element 85 and the switch 86 are connected in series, and these are provided in parallel with the capacitive element 84. The capacitance value of the capacitive portion 82 is different and the gain of the charge amplifier 80 is different according to whether the switch 86 is in an ON state or in an OFF state. Turning ON and OFF of the switch 86 is controlled by the control signal given from the control unit 30.

The reset switch 83 is provided in parallel with the capacitive portion 82 between the inverting input terminal and the output terminal of the amplifier 81. When the reset switch 83 is in an ON state, charge accumulation in the capacitive portion 82 is reset. When the reset switch 83 is in an OFF state, a voltage value according to the charge accumulation amount in the capacitive portion 82 and the capacitance value of the capacitive portion 82 is output from the output terminal of the amplifier 81. Turning ON and OFF of the reset switch 83 is controlled by the control signal given from the control unit 30.

FIG. 5 is a timing chart illustrating an operation of the second configuration example of each unit 10ₙ. Turning ON and OFF switching timings of the operation control switch 62, the switches 22₁ to 22_{N}, and the switches 23₁ to 23_{N} are the same as those illustrated in FIG. 3. Therefore, in the case of the second configuration example, it is possible to suppress power consumption, as in the case of the first configuration example.

In the case of the second configuration example, in a period in which the operation control switch 62 is in an OFF state, the reset switch 83 enters an ON state and the charge accumulation in the capacitive portion 82 is reset. Further, in a period in which the reset switch 83 is in an ON state, the switch 86 is switched between ON and OFF and the capacitance value of the capacitive portion 82 is changed. In the period in which the operation control switch 62 is in an OFF state, each of the reset switch 83 and the switch 86 is switched between ON and OFF in the charge amplifier 80. Therefore, even when noise is generated at the time of switching between ON and OFF of these switches, an influence of the noise on the photodiode 50 and the source follower amplifier 60 can be suppressed, and a stable operation becomes possible.

In addition, in the operation example of the above embodiment, the N units 10₁ to 10_{N} operate at the same timing, but the N units 10₁ to 10_{N} may sequentially operate and sequentially output voltage values.

The present invention is not limited to the above embodiment and the configuration examples, and various modifications are possible.

The linear image sensor according to the above embodiment is a linear image sensor in which a plurality of units each outputting a voltage value according to an incident light amount are arranged one-dimensionally. In the linear image sensor of the above configuration, each of the plurality of units is configured to include (1) a photodiode for generating a charge according to light incidence, and (2) a source follower amplifier including a MOS transistor having a gate connected to one terminal of the photodiode and a drain connected to a first reference potential input terminal, an operation control switch provided between a source of the MOS transistor and a connection node, and a current source provided between the connection node and a second reference potential input terminal, the source follower amplifier for outputting a voltage value according to a voltage value of the gate of the MOS transistor from the connection node in a period in which the operation control switch is in an ON state.

In the linear image sensor of the above configuration, each of the plurality of units may further include (3) a charge amplifier including an amplifier having an input terminal and an output terminal, a capacitive portion provided between the input terminal and the output terminal of the amplifier and for accumulating a charge of an amount according to the voltage value output from the source follower amplifier, and a reset switch provided in parallel with the capacitive portion between the input terminal and the output terminal of the amplifier and for resetting charge accumulation in the capacitive portion, the charge amplifier for outputting a voltage value according to the charge accumulation amount in the capacitive portion.

In the linear image sensor of the above configuration, the charge amplifier may be configured such that the reset switch enters an ON state to reset the charge accumulation in the capacitive portion in a period in which the operation control switch is in an OFF state.

Further, in the linear image sensor of the above configuration, the charge amplifier may be configured such that the capacitive portion has a variable capacitance value, and a voltage value according to the charge accumulation amount in the capacitive portion and the capacitance value is output.

Further, in the linear image sensor of the above configuration, the charge amplifier may be configured such that the capacitance value of the capacitive portion is changed in a period in which the reset switch is in an ON state.

### INDUSTRIAL APPLICABILITY

The present invention can be used as a linear image sensor capable of suppressing power consumption.

### REFERENCE SIGNS LIST

1—linear image sensor, 10₁ to 10_{N}—unit, 20—readout circuit, 21₁ to 21_{N}—hold circuit, 22₁ to 22_{N}—switch, 23₁ to 23_{N}—switch, 30—control unit, 40—video line, 50—photodiode, 51, 52—MOS transistor, 60—source follower amplifier, 61—MOS transistor, 62—operation control switch, 63—current source, 64—connection node, 70—capacitive element, 80—charge amplifier, 81—amplifier, 82—capacitive portion, 83—reset switch, 84, 85—capacitive element, 86—switch.

1. A linear image sensor comprising a plurality of units each outputting a voltage value according to an incident light amount arranged one-dimensionally, wherein
each of the plurality of units comprises:
a photodiode configured to generate a charge according to light incidence; and
a source follower amplifier including a MOS transistor having a gate connected to one terminal of the photodiode and a drain connected to a first reference potential input terminal, an operation control switch provided between a source of the MOS transistor and a connection node, and a current source provided between the connection node and a second reference potential input terminal, the source follower amplifier configured to output a voltage value according to a voltage value of the gate of the MOS transistor from the connection node in a period in which the operation control switch is in an ON state.

2. The linear image sensor according to claim 1, wherein
each of the plurality of units further comprises:
a charge amplifier including an amplifier having an input terminal and an output terminal, a capacitive portion provided between the input terminal and the output terminal of the amplifier and configured to accumulate a charge of an amount according to the voltage value output from the source follower amplifier, and a reset switch provided in parallel with the capacitive portion between the input terminal and the output terminal of the amplifier and configured to reset charge accumulation in the capacitive portion, the charge amplifier configured to output a voltage value according to the charge accumulation amount in the capacitive portion.

3. The linear image sensor according to claim 2, wherein in the charge amplifier, the reset switch enters an ON state to reset the charge accumulation in the capacitive portion in a period in which the operation control switch is in an OFF state.

4. The linear image sensor according to claim 2, wherein in the charge amplifier, the capacitive portion has a variable capacitance value, and a voltage value according to the charge accumulation amount in the capacitive portion and the capacitance value is output.

5. The linear image sensor according to claim 4, wherein in the charge amplifier, the capacitance value of the capacitive portion is changed in a period in which the reset switch is in an ON state.
